(19) United States
(12) Patent Application Publication
(10) Pub. No.: US 2023/0323122 A1
(43) Pub. Date: Oct. 12, 2023

(54) CURABLE SILICONE COMPOSITION

(71) Applicant: DuPont Toray Specialty Materials Kabushiki Kaisha, Tokyo (JP)

(72) Inventors: Shunya TAKEUCHI, Chiba (JP); Akihiko KOBAYASHI, Chiba (JP)

(21) Appl. No.: 18/178,161

(22) Filed: Mar. 3, 2023

(30) Foreign Application Priority Data
Mar. 10, 2022 (JP) 2022-037540

(51) Int. Cl. C08L 83/04; H01L 33/56

(52) U.S. Cl. CPC C08L 83/04; H01L 33/56; C08L 2203/20; H01L 33/005

(57) ABSTRACT

A curable silicone composition of the present invention includes (A) straight-chain organopolysiloxane which has at least two alkenyl groups bound to a silicon atom and ≥0 mol% and <5 mol% of aryl groups per molecule, (B) organopolysiloxane resin which has at least two alkenyl groups bound to a silicon atom per molecule: 0-10 mass% based on the total mass of organopolysiloxane having alkenyl groups bound to a silicon atom and organopolysiloxane having hydrogen atoms bound to a silicon atom in the composition; (C) an organohydrogenpolysiloxane resin which a specific molecular structure in the form of a network, with at least two hydrogen atoms bound to a silicon atom per molecule: and (E) a hydrosilylation reaction catalyst; and mols of SiH/mols of Si-bound alkenyl groups in the total quantity of organopolysiloxane = 1-3.

### CROSS-REFERENCE TO RELATED APPLICATIONS

This application claims priority pursuant to 35 U.S.C. 119(a) to Japanese Application No. 2022-037540, filed Mar. 10, 2022, which application is incorporated herein by reference in its entirety.

### TECHNICAL FIELD

This disclosure relates to curable silicone compositions, hardened material thereof, semiconductor sealing material compositions comprising such a composition, semiconductor devices wherein a semicond element is sealed with such a composition, and a process for producing semiconductor devices.

### BACKGROUND ART

Hardened material from a curable silicone composition cured by a hydrosilylation reaction is known to have various characteristics such as water-repellency, transparency, heat resistance, low-temperature resistance, electrical insulating properties and weather resistance. Consequently, various curable silicone compositions have found wide industrial applications. For Example, JP 2010-174233 A (Patent Document 1) describes curable silicone compositions which include an alkenyl-group-containing alkylpolysiloxane, a resinous alkenyl-group-containing organopolysiloxane, an organopolysiloxane which has hydrogen atoms bound to a silicon atom, and has SiO4/2 units, a straight-chain organopolysiloxane which has hydrogen atoms bound to a silicon atom and a hydrosilylation reaction catalyst. An example in Patent Document 1 mentions that the curable silicone composition is press-cured for 10 minutes at 120° C., and treated at 200° C. for a further 4 hours.

JP 2018-131583 A (Patent Document 2) mentions employing a curable silicone composition which includes a straight-chain organopolysiloxane which has at least two alkenyl groups, a branched organopolysiloxane which has at least two alkenyl groups, a branched organohydrogenpolysiloxane containing at least two hydrogen atoms bound to a silicon atom, a straight-chain organohydrogenpolysiloxane containing at least two hydrogen atoms bound to a silicon atom, and a solvent, as die-attach material for photosemiconductor devices. JP 2016-155967 A (Patent Document 3) mentions employing a curable silicone composition which includes a straight-chain organopolysiloxane which has at least two alkenyl groups, a branched organopolysiloxane which has at least two alkenyl groups, a straight-chain organohydrogenpolysiloxane containing at least two hydrogen atoms bound to a silicon atom, and an addition reaction catalyst, as die-attach material for photosemiconductor devices. JP 2006-328102 A (Patent Document 4) describes silicone resin compositions for forming lenses, which include an organopolysiloxane which has at least two aliphatic unsaturated carbon bonds per molecule, a branched organohydrogenpolysiloxane having at least three hydrogen atoms bound to a silicon atom per molecule, and a platinum-group metal catalyst. An example in Citation 4 mentions moulding the curable silicone composition for forming lenses at 150° C. for 90 seconds.

In particular, hardened material which is less prone than other organic materials to colouration, and shows little decrease in physical properties is suitable for covering and/or sealing optical elements. For example, WO 2018/062009 A (Patent Document 5) indicates that a photosemiconductor element is sealed by a cured product of a curable silicone composition comprising at least: a straight-chain organopolysiloxane which has at least two silicon-atom-bound alkenyl groups per molecule, and in which at least 5 mol% of the total organic groups bound to a silicon atom are aryl groups; organopolysiloxane comprising siloxane units represented by the formula R13SiO1/2 (in the formula the R1s are the same or different monovalent hydrocarbon groups) and siloxane units represented by the formula SiO4/2, in which the alkenyl group content is at least 6 wt%; organopolysiloxane which has at least two hydrogen atoms per molecule bound to a silicon atom; and a hydrosilylation reaction catalyst. In addition, Patent Document 5 describes, in Comparative Example 5, a composition which includes 88 wt% of a straight-chain organopolysiloxane which has at least two alkenyl groups and does not have aryl groups as any of the silicon-atom-bound organic groups, based on the total quantity of polysiloxane groups which can contribute to the hydrosilylation reaction; 5.1 wt% of a vinyl-group-containing organopolysiloxane MQ resin; 6.1 wt% of an organohydrogenpolysiloxane MQ resin; and 0.5 wt% of a condensation product of a methylvinyl siloxane oligomer with a terminal silanol group at both ends of the molecule and 3-glycidoxypropyltrimethoxysilane.

JP 2016-204423 A (Patent Document 6) describes covering light-emitting elements with hardened material of an addition-cured silicone composition which includes an organopolysiloxane with a network structure, which has at least two alkenyl groups per molecule, a straight-chain organopolysiloxane which has at least two alkenyl groups per molecule, a branched organohydrogenpolysiloxane which has at least two alkenyl groups per molecule, a straight-chain organohydrogenpolysiloxane which has at least two alkenyl groups per molecule, and a hydrosilylation catalyst. JP 2015-218233 A (Patent Document 7) mentions sealing photosemiconductors with curable organopolysiloxane composition which includes an organopolysiloxane which has at least two alkenyl groups, an organohydrogenpolysiloxane, and an addition reaction catalyst.

JP 2009-292928 A (Patent Document 8) describes heat-conducting silicone compositions which include a straight-chain organopolysiloxane which has at least two alkenyl groups per molecule, an organohydrogenpolysiloxane comprising only M units, D units and T units, and a straight-chain organohydrogenpolysiloxane. JP 10-231428 A (Patent Document 9) describes, in Comparative Example 3, a composition which includes 100 parts by weight of dimethylpolysiloxane with both ends of the molecular chain capped with dimethylvinylsilyl groups and 1.6 parts by weight of a branched hydrogenpolysiloxane compound.

However, heat-curing at a high temperature for a long time may be necessary in order to form hardened material from curable silicone compositions cured by a hydrosilylation reaction. For example, the examples of Patent Documents 2, 3, 5, 6 and 7 discussed above mention that the curable silicone compositions were cured by heating at 150° C. for at least 1 hour. This long curing time leads to lowered productivity. Moreover, when heating for a long time at a high temperature is necessary in order to cure a curable silicone composition, the electronic device on which the curable silicone composition is used may be damaged by heating. Because of this, there is a demand for curable silicone compositions which can be cured in a short time at a low temperature. Increasing the quantity of hydrosilylation catalyst could be considered as one way of curing curable silicone compositions in a short time at a low temperature. However, when there is a large quantity of hydrosilylation catalyst in a curable silicone composition, there is marked colouration of the hardened material, and it may not be usable for applications requiring transparent hardened material, such as the sealing of photosemiconductor elements, etc.

Moreover, curable silicone compositions cured by a hydrosilylation reaction may undergo considerable shrinkage in volume during curing. This volume shrinkage can cause curling of flexible films and decreased precision in controlling flatness and thickness. Moreover, in order to heighten process efficiency in processes such as sealing photosemiconductor elements with a curable silicone composition, it is important that the curable silicone composition has a low viscosity. In addition, low viscosity in the curable silicone composition is important for self-levelling properties required in screen-printing processes, etc.

### PRIOR ART DOCUMENTS

### Patent Documents

[Patent Document 1] JP 2010-174233 A
[Patent Document 2] JP 2018-131583 A
[Patent Document 3] JP 2016-155967 A
[Patent Document 4] JP 2006-328102 A
[Patent Document 5] WO 2018/062009 A1
[Patent Document 6] JP 2016-204423 A
[Patent Document 7] JP 2015-218233 A
[Patent Document 8] JP 2009-292928 A
[Patent Document 9] JP 10-231428 A

### SYNOPSIS OF THE INVENTION

### Problem Which the Invention is Intended to Solve

The object of the present invention is to offer curable silicone compositions which can be cured at low temperature in a short time, and which show little volume shrinkage during curing, have a low catalyst content and have a low viscosity.

### Means for Solving the Problem

As the result of concerted studies directed towards the problem above, it was discovered that, in curable silicone compositions cured by a hydrosilylation reaction, the object of the present invention is achieved by including straight-chain organopolysiloxane which has at least two silicon-atom-bound alkenyl groups and organohydrogenpolysiloxane containing at least two hydrogen atoms bound to a silicon atom, restricting the content of the organopolysiloxane which has at least two silicon-atom-bound alkenyl groups, and specifying the ratio of the total mols of hydrogen atoms bound to a silicon atom in the total organopolysiloxane included in the composition relative to the total mols of alkenyl groups bound to a silicon atom in the total organopolysiloxane included in the composition.

In order to solve the aforementioned problem, one aspect of the present invention offers a curable silicone composition below:
which is a curable silicone composition comprising
   (A) straight-chain organopolysiloxane which has at least two alkenyl groups bound to a silicon atom per molecule, and a quantity of aryl groups bound to a silicon atom of ≥0 mol% and <5 mol% based on the total mols of organic groups bound to a silicon atom: 89-99 mass% based on the total mass of organopolysiloxane having alkenyl groups bound to a silicon atom and organopolysiloxane having hydrogen atoms bound to a silicon atom in the aforementioned composition,
   (B) organopolysiloxane resin which has at least two alkenyl groups bound to a silicon atom per molecule: 0-10 mass% based on the total mass of organopolysiloxane having alkenyl groups bound to a silicon atom and organopolysiloxane having hydrogen atoms bound to a silicon atom in the aforementioned composition,
   (C) organohydrogenpolysiloxane resin which has a network molecular structure with at least two hydrogen atoms bound to a silicon atom per molecule, selected from the group consisting of (C1) organohydrogenpolysiloxane resins which have a network molecular structure which has at least two hydrogen atoms bound to a silicon atom per molecule, and includes a siloxane unit represented by SiO4/2 (Q unit), and
   (C2) organohydrogenpolysiloxane resins having a network molecular structure which has at least two hydrogen atoms bound to a silicon atom per molecule, includes a siloxane unit represented by R3SiO3/2 (T unit) and a siloxane unit represented by R33SiO½ (M unit), and does not include a siloxane unit represented by R32SiO2/2 (D unit) or a siloxane unit represented by SiO4/2 (Q unit), (in the formulae, each of the R3s, which can be the same or different, is a monovalent hydrocarbon group which does not have an aliphatic unsaturated carbon bond, or a hydrogen atom): 1-11 mass% based on the total mass of organopolysiloxane having alkenyl groups bound to a silicon atom and organopolysiloxane having hydrogen atoms bound to a silicon atom in the aforementioned composition, and
   (E) a hydrosilylation reaction catalyst: a quantity, which is a catalytic quantity, of <15 ppm as the quantity of metal atoms included in the catalyst based on the total mass of organopolysiloxane having alkenyl groups bound to a silicon atom and organopolysiloxane having hydrogen atoms bound to a silicon atom in the aforementioned composition,
wherein (total mols of hydrogen atoms bound to a silicon atom in the total organopolysiloxane included in the composition) / (total mols of alkenyl groups bound to a silicon atom in the total organopolysiloxane included in the composition) = 1-3.

One aspect of the present invention offers hardened material of a curable silicone composition described above.

One aspect of the present invention offers photosemiconductor sealing material compositions comprising a curable silicone composition described above.

One aspect of the present invention offers photosemiconductor devices in which the photosemiconductor elements are sealed with hardened material of curable silicone composition described above.

Moreover, one aspect of the present invention offers a process for producing photosemiconductor devices, which includes sealing photosemiconductor elements with hardened material of a curable silicone composition described above.

### Effects of the Invention

The curable silicone compositions in one embodiment of the present invention present the effects that curing is possible in a short time and at low temperature, viscosity is low, there is little volume shrinkage during hardening of the curable silicone composition, and there is little change in the colour of the hardened material.

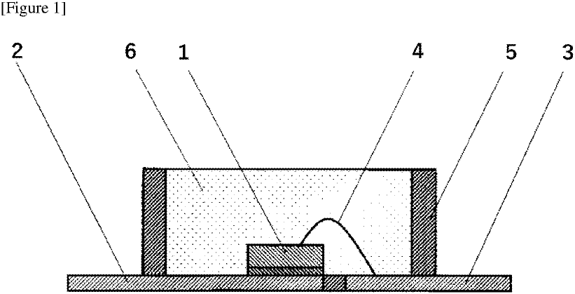

### SIMPLIFIED DESCRIPTION OF THE DRAWINGS

[FIG. 1] is a cross-sectional drawing of an LED which is an example of a photosemiconductor device of the present invention.

### MODE FOR CARRYING OUT THE INVENTION

Constituent (A) in a curable silicone composition of the present invention is a straight-chain organopolysiloxane which has at least two alkenyl groups bound to a silicon atom per molecule, and a total quantity of aryl groups bound to a silicon atom of ≥0 mol%and <5 mol%based on the total mols of organic groups bound to a silicon atom. Constituent (A) can be one of the principal agents (base polymers) in the composition. In one embodiment of the present invention, the quantity of constituent (A) included in the curable silicone composition, based on the total mass of organopolysiloxane having alkenyl groups bound to a silicon atom and organopolysiloxane having hydrogen atoms bound to a silicon atom in the composition, can be 89-99 mass%, and is preferably 90-99 mass%, more preferably 91-99 mass%, and even more preferably 92-98 mass%. In one embodiment of the present invention, the quantity of constituent (A) included in the curable silicone composition, based on the total mass of organopolysiloxane having alkenyl groups bound to a silicon atom and organopolysiloxane having hydrogen atoms bound to a silicon atom in the aforementioned composition, can be 89-98 mass%.

In the descriptions “based on the total mass of organopolysiloxane having alkenyl groups bound to a silicon atom and organopolysiloxane having hydrogen atoms bound to a silicon atom in the aforementioned composition,” and “(total mols of hydrogen atoms bound to a silicon atom in the total organopolysiloxane included in the composition)/(total mols of alkenyl groups bound to a silicon atom in the total organopolysiloxane included in the composition)” in this specification, the term “organopolysiloxane” includes straight-chain organopolysiloxanes and organopolysiloxane resins; and there is no particular restriction as to the structure of the organopolysiloxanes specified by this term “organopolysiloxane”. In this specification, constituent (A) and constituent (B) fall into the category of “organopolysiloxane having alkenyl groups bound to a silicon atom”. Moreover, “organopolysiloxane having alkenyl groups bound to a silicon atom” can also include organopolysiloxanes other than constituent (A) and constituent (B), such as, for example, straight-chain organopolysiloxane having one alkenyl group bound to a silicon atom, straight-chain organopolysiloxane which has at least two alkenyl groups bound to a silicon atom per molecule, and a quantity of aryl groups bound to a silicon atom of ≥5 mol% based on the total mols of organic groups bound to a silicon atom, organopolysiloxane resin having one alkenyl group bound to a silicon atom, and organopolysiloxane having alkenyl groups bound to a silicon atom, employed as an agent conferring adhesion (G).

In this specification, constituent (C), and constituent (D) “straight-chain organohydrogenpolysiloxane containing at least two hydrogen atoms bound to a silicon atom”, discussed later, fall into the category of “organopolysiloxane having hydrogen atoms bound to a silicon atom”. On the other hand, “organopolysiloxane having hydrogen atoms bound to a silicon atom” can also include organopolysiloxanes other than constituent (C) and constituent (D), such as, for example, organohydrogenpolysiloxane resins which have at least two hydrogen atoms bound to a silicon atom per molecule and have a network molecular structure but do not fall into the category of (C1) or (C2), organohydrogenpolysiloxane resins which have at least two hydrogen atoms bound to a silicon atom per molecule and have a branched chain (not network) molecular structure, organohydrogenpolysiloxane resins containing one hydrogen atom bound to a silicon atom and straight-chain organohydrogenpolysiloxanes containing one hydrogen atom bound to a silicon atom.

Examples of alkenyl groups in constituent (A) include C2-12 alkenyl groups such as a vinyl group, allyl group, butenyl group, pentenyl group, hexenyl group, cyclohexenyl group, heptenyl group, octenyl group, nonenyl group, decenyl group, undecenyl group, and dodecenyl group; a vinyl group is preferred. In addition, examples of organic groups other than alkenyl groups bound to a silicon atom in constituent (A) include C1-12 monovalent hydrocarbon groups which do not have an aliphatic unsaturated carbon bond; specific examples include C 1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group, C6-12 aryl groups such as a phenyl group, tolyl group, xylyl group and naphthyl group, C7-12 aralkyl groups such as a benzyl group, phenethyl group and phenylpropyl group, and these groups in which some or all of the hydrogen atoms are replaced by a halogen atom such as a fluorine atom, chlorine atom or bromine atom, for example halogen-substituted C1-12 alkyl groups such as a 3-chloropropyl group and a 3,3,3-fluoropropyl group. However, in constituent (A) the quantity of aryl groups bound to a silicon atom, based on the total mols of organic groups bound to a silicon atom, is ≥0 mol% and <5 mol% and preferably ≥0 mol% and ≤2 mol%, and more preferably 0 mol%.

The straight-chain alkenyl-group-containing organopolysiloxane of constituent (A) can have alkenyl groups bound to a silicon atom only at the ends of the molecule, can have them only in a diorganosiloxane repeating unit of the molecule, or can have them both at the end of the molecule and in a diorganosiloxane repeating unit of the molecule. In one embodiment of the present invention, the straight-chain alkenyl-group-containing organopolysiloxane of constituent (A) has alkenyl groups bound to a silicon atom only at both ends of the molecule.

For example, the straight-chain alkenyl-group-containing organopolysiloxane of constituent (A) can be represented by the general formula:

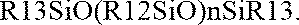

In the formula the R1s are the same or different monovalent hydrocarbon groups; specific examples include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C2-12 alkenyl groups such as a vinyl group, allyl group, butenyl group, pentenyl group, hexenyl group, cyclohexenyl group, heptenyl group, octenyl group, nonenyl group, decenyl group, undecenyl group and dodecenyl group, C6-12 aryl groups such as a phenyl group, tolyl group, xylyl group and naphthyl group; C7-12 aralkyl groups such as a benzyl group, phenethyl group and phenylpropyl group; and halogen-substituted C1-12 alkyl groups, such as a 3-chloropropyl group and a 3,3,3-fluoropropyl group. However, at least two R1s are alkenyl groups, and ≥0 mol% and <5 mol% of all R1s are aryl groups. In addition, in the formula n is an integer ≥1, and is preferably an integer 10-1000, and more preferably an integer 30-800.

Examples of constituent (A) include dimethylpolysiloxane with both ends of the molecular chain capped with dimethylvinylsiloxy groups, a dimethylsiloxane/methylphenylsiloxane copolymer with both ends of the molecular chain capped with dimethylvinylsiloxy groups, a dimethylsiloxane/methylvinylsiloxane copolymer with both ends of the molecular chain capped with dimethylvinylsiloxy groups, a dimethylsiloxane/methylvinylsiloxane copolymer with both ends of the molecular chain capped with trimethylsiloxy groups, and a dimethylsiloxane/methylvinylsiloxane/methylphenylsiloxane copolymer with both ends of the molecular chain capped with trimethylsiloxy groups, and mixtures of two or more thereof. In one embodiment of the present invention, constituent (A) can be dimethylpolysiloxane with both ends of the molecular chain capped with dimethylvinylsiloxy groups. A single constituent (A) can be employed, or two or more can be used together.

In one embodiment of the present invention, constituent (A) has a number-average molecular weight of ≤200,000, and preferably has a number average molecular weight of ≤150,000 and more preferably ≤100,000. An organopolysiloxane of constituent (A) preferably has a number-average molecular weight of at least 1000, and more preferably has a number average molecular weight of at least 1500. The values for number-average molecular weight (Mn) and weight-average molecular weight (Mw) in this specification are values measured by gel permeation chromatography using polystyrene standards. In one embodiment of the present invention, the viscosity of constituent (A) at 25° C. is preferably in the range 1-200,000 mPa.s, and more preferably in the range 5-100,000 mPa.s. The viscosity of substances in this specification are viscosities measured at 25° C. with a rotating viscometer in accordance with JIS K7117-1.

Constituent (B) in a curable silicone composition of the present invention is organopolysiloxane resin which has at least two alkenyl groups bound to a silicon atom per molecule. Constituent (B) can be one of the principal agents (base polymers) in the composition. The organopolysiloxane resin as constituent (B) in the present invention includes at least one siloxane unit selected from a group consisting of siloxane units represented by R2SiO3/2 (R2 is a monovalent hydrocarbon group) (T units) and siloxane units represented by SiO4/2 (Q units), and is an organopolysiloxane resin which has at least two alkenyl groups bound to a silicon atom per molecule. The molecular structure of the organopolysiloxane resin of constituent (B) can be a branching structure or a network structure; it is preferably a network structure.

Constituent (B) is a discretionary constituent in the curable silicone composition: a constituent (B) can be included, but need not be included. The quantity of constituent (B), based on the total mass of organopolysiloxane having alkenyl groups bound to a silicon atom and organopolysiloxane having hydrogen atoms bound to a silicon atom in the curable silicone composition, can be 0-10 mass% and is preferably 0-9 mass%, and more preferably 0-8 mass%. When the quantity of constituent (B) in the composition based on the total mass of organopolysiloxane having alkenyl groups bound to a silicon atom and organopolysiloxane having hydrogen atoms bound to a silicon atom exceeds 20 mass%, curing of the composition becomes slow.

Specific examples of R2 as a monovalent hydrocarbon group include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C2-12 alkenyl groups such as a vinyl group, allyl group, butenyl group, pentenyl group, hexenyl group, cyclohexenyl group, heptenyl group, octenyl group, nonenyl group, decenyl group, undecenyl group and dodecenyl group; C6-12 aryl groups such as a phenyl group, tolyl group, xylyl group and naphthyl group; C7-12 aralkyl groups such as a benzyl group, phenethyl group and phenylpropyl group; and these groups in which some or all of the hydrogen atoms are substituted with a halogen atom such as a fluorine atom, chlorine atom or bromine atom, for example halogen-substituted C1-12 alkyl groups such as a 3-chloropropyl group and a 3,3,3-fluoropropyl group.

Examples of alkenyl groups included in constituent (B) include C2-12 alkenyl groups such as a vinyl group, allyl group, butenyl group, pentenyl group, hexenyl group, cyclohexenyl group, heptenyl group, octenyl group, nonenyl group, decenyl group, undecenyl group, and dodecenyl group; a vinyl group is preferred.

In one embodiment, constituent (B) is organopolysiloxane resin which has at least two alkenyl groups bound to a silicon atom per molecule, and is represented by the average compositional formula below:

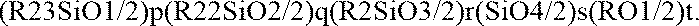

In the formula, each of the R2s, which can be the same or different, is a monovalent hydrocarbon group with at least two R2s per molecule being alkenyl groups; R is a hydrogen atom or a C1-10 alkyl group; p, q, r, s and t represent the respective molar ratios, and the numbers satisfy the following relationships: 0≤p, 0≤q, 0≤r, 0≤s, 0≤t≤0.1, where r+s>0, and p+q+r+s+t=1.

Preferably, 0≤p≤0.8, 0≤q≤0.5, 0≤r≤0.8, 0≤s≤0.8, 0.1≤r+s≤0.8, and p+q+r+s+t=1, More preferably, 0.2≤r+s≤0.7, and even more preferably r+s is ≥0.3, and especially preferably r+s is ≥0.35.

Specific examples of R2 as a monovalent hydrocarbon group include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C2-12 alkenyl groups such as a vinyl group, allyl group, butenyl group, pentenyl group, hexenyl group, cyclohexenyl group, heptenyl group, octenyl group, nonenyl group, decenyl group, undecenyl group and dodecenyl group; C6-12 aryl groups such as a phenyl group, tolyl group, xylyl group and naphthyl group; C7-12 aralkyl groups such as a benzyl group, phenethyl group and phenylpropyl group; and these groups in which some or all of the hydrogen atoms are substituted with a halogen atom such as a fluorine atom, chlorine atom or bromine atom, for example halogen-substituted C1-12 alkyl groups such as a 3-chloropropyl group and a 3,3,3-fluoropropyl group. Monovalent hydrocarbon groups as R2 other than alkenyl groups are preferably a methyl group or phenyl group, and more preferably a methyl group.

Examples of alkenyl groups included in constituent (B) in the formula above include C2-12 alkenyl groups such as a vinyl group, allyl group, butenyl group, pentenyl group, hexenyl group, cyclohexenyl group, heptenyl group, octenyl group, nonenyl group, decenyl group, undecenyl group, and dodecenyl group; a vinyl group is preferred.

In one embodiment of the present invention, constituent (B) is represented by the formula:

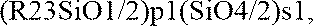

in the formula the R2s are monovalent hydrocarbon groups above, and at least two R2s are alkenyl groups; p1+s1=1, preferably 0.02≤pl≤0.8 and 0.2≤s1≤0.98, and more preferably 0.5≤pl≤0.7 and 0.3≤s1≤0.5.

In one embodiment of the present invention, constituent (B) is represented by the formula:

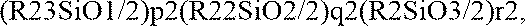

in the formula the R2s are monovalent hydrocarbon groups above, at least two R2s are alkenyl groups, and p2, q2 and r2 satisfy, respectively, 0≤p2≤0.8, 0≤q2≤0.5, 0.1≤r2≤0.9, and p2+q2+r2=1.

In one embodiment of the present invention, the organopolysiloxane resin of constituent (B) can be in the liquid state at 25° C., or can be in the solid state at 25° C. In one embodiment of the present invention, the organopolysiloxane resin of constituent (B) is in the solid state at 25° C.

Constituent (C) in a curable silicone composition of the present invention is an organohydrogenpolysiloxane resin which has a network molecular structure with at least two hydrogen atoms bound to a silicon atom per molecule, selected from a group consisting of (C1) and (C2) below:
(C1) organohydrogenpolysiloxane resins which have a network molecular structure with at least two hydrogen atoms bound to a silicon atom per molecule, and include a siloxane unit represented by SiO4/2 (Q unit), and
(C2) organohydrogenpolysiloxane resins which have a network molecular structure with at least two hydrogen atoms bound to a silicon atom per molecule, include a siloxane unit represented by R3SiO3/2 (T unit) and a siloxane unit represented by R33SiO½ (M unit), and do not include a siloxane unit represented by R32SiO2/2 (D unit) or a siloxane unit represented by SiO4/2 (Q unit), (in the formulae, each of the R3s, which can be the same or different, is a monovalent hydrocarbon group which does not have an aliphatic unsaturated carbon bond, or a hydrogen atom).

Constituent (C) can function in the composition as a crosslinking agent. In one embodiment, the organohydrogenpolysiloxane resin of constituent (C) does not have an aliphatic unsaturated carbon bond. In one embodiment of the present invention, the quantity of constituent (C) included in the curable silicone composition, based on the total mass of organopolysiloxane having alkenyl groups bound to a silicon atom and organopolysiloxane having hydrogen atoms bound to a silicon atom in the composition, can be 1-11 mass%, and is preferably 1-5 mass%, more preferably 2-5 mass%, and even more preferably 3-4 mass%.

In one embodiment of the present invention, (C1), an organohydrogenpolysiloxane resin which has a network molecular structure, with at least two hydrogen atoms bound to a silicon atom per molecule and includes a siloxane unit represented by SiO4/2 (Q unit), is represented by the average compositional formula below:

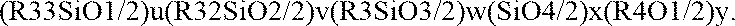

In the formula, each of the R3s, which can be the same or different, is a monovalent hydrocarbon group which does not have an aliphatic unsaturated carbon bond, or a hydrogen atom, with at least two R3s per molecule being hydrogen atoms; R4 is a hydrogen atom or a C1-10 alkyl group; u, v, w, x and y represent the respective molar ratios, and the numbers satisfy the following relationships: 0≤u, 0≤v, 0≤w, 0<x, 0≤y≤0.10, where u+v+w+x+y=1.

Preferably, 0.1≤u≤0.8, 0≤v≤0.5, 0≤w<0.8, 0<x≤0.8, 0≤y≤0.1, 0.1≤w+x≤0.8, and u+v+w+x+y=1. More preferably,0.2≤w+x≤0.6, even more preferably, w+x is ≥0.3 and especially preferably ≥0.35.

In one embodiment, (C2), an organohydrogenpolysiloxane resin which has a network molecular structure with at least two hydrogen atoms bound to a silicon atom per molecule, includes a siloxane unit represented by R3SiO3/2 (T unit) and a siloxane unit represented by R33SiO1/2 (M unit), and does not include a siloxane unit represented by R32SiO2/2 (D unit) or a siloxane unit represented by SiO4/2 (Q unit), (in the formulae, each of the R3s, which can be the same or different is a monovalent hydrocarbon group which does not have an aliphatic unsaturated carbon bond, or a hydrogen atom), is represented by the following average compositional formula:

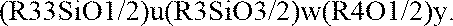

In the formula, each of the R3s, which can be the same or different is a monovalent hydrocarbon group which does not have an aliphatic unsaturated carbon bond, or a hydrogen atom, with at least two R3s per molecule being hydrogen atoms; R4 is a hydrogen atom or a C1-10 alkyl group; u, w and y represent the respective molar ratios, and the numbers satisfy the following relationships: 0<u, 0<v, 0≤y≤0.10, where u+w+y=1.

Preferably, 0.1≤u≤0.8, 0≤v≤0.5, 0≤w<0.8, 0<x≤0.8, 0≤y≤0.1, 0.1≤w+x≤0.8, and u+v+w+x+y=1. More preferably,0.2≤w+x≤0.6, even more preferably, w+x is ≥0.3 and especially preferably ≥0.35.

Specific examples of monovalent hydrocarbon groups as R3 include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C6-12 aryl groups such as a phenyl group, tolyl group, xylyl group and naphthyl group; C7-12 aralkyl groups such as a benzyl group, phenethyl group and phenylpropyl group; and these groups in which some or all of the hydrogen atoms are substituted with a halogen atom such as a fluorine atom, chlorine atom or bromine atom, for example halogen-substituted C1-12 alkyl groups such as a 3-chloropropyl group and a 3,3,3-fluoropropyl group. Monovalent hydrocarbon groups as R3 are preferably a methyl group or phenyl group, and more preferably a methyl group.

R4 is preferably a hydrogen atom, a methyl group or an ethyl group, in these cases, OR4 is a hydroxyl group, a methoxy group or an ethoxy group.

In one embodiment of the present invention, the organohydrogenpolysiloxane resin of constituent (C) is represented by the formula:

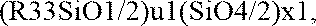

in the formula the R3s are a monovalent hydrocarbon group or a hydrogen atom, and at least two R3s are alkenyl groups; are hydrogen atoms, and u1+x1=1; preferably, 0.1≤ul≤0.8 and 0.2≤x1≤0.9, and more preferably 0.5≤ul≤0.7 and 0.3≤x1≤0.5.

In one embodiment of the present invention, the organohydrogenpolysiloxane resin of constituent (C) is represented by the formula:

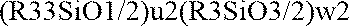

in the formula the R3s are a monovalent hydrocarbon group or a hydrogen atom, and at least two R3s are hydrogen atoms, and u2 and w2 are, respectively, 0.1≤u2≤0.9 and 0.1≤w2≤0.9, and the numbers satisfy u2+w2=1.

In one embodiment of the present invention, the viscosity of the organohydrogenpolysiloxane resin of constituent (C) at 25° C. is in the range 0.1-10,000 mPa.s, preferably in the range 0.5-5,000 mPa.s, and more preferably in the range 1-1000 mPa.s. A single constituent (C) can be employed, or two or more can be used together. In one embodiment of the present invention, the organohydrogenpolysiloxane resin of constituent (C) has a weight-average molecular weight (Mw) of ≥500, preferably has Mw ≥550, and more preferably has Mw ≥700. In one embodiment of the present invention, the organohydrogenpolysiloxane resin of constituent (C) preferably has Mw ≤100,000, and more preferably has Mw ≤10,000.

A curable silicone composition of the present invention can include as a discretionary constituent (D), a straight-chain organohydrogenpolysiloxane containing at least two hydrogen atoms bound to a silicon atom. Constituent (D) can function in the composition as a crosslinking agent. In one embodiment of the present invention, the quantity of constituent (D) included in the curable silicone composition, based on the total mass of organopolysiloxane having alkenyl groups bound to a silicon atom and organopolysiloxane having hydrogen atoms bound to a silicon atom in the composition, is preferably 0-10 mass%, and more preferably 0-5 mass%. In one embodiment, the curable silicone composition of the present invention does not include a constituent (D). In one embodiment, the straight-chain organohydrogenpolysiloxane of constituent (D) does not have an aliphatic unsaturated carbon bond.

Examples of organic groups bound to a silicon atom in constituent (D) include C1-12 monovalent hydrocarbon groups which do not have an aliphatic unsaturated carbon bond, and specific examples include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C6-12 aryl groups such as a phenyl group, tolyl group, xylyl group and naphthyl group; C7-12 aralkyl groups such as a benzyl group, phenethyl group and phenylpropyl group; and these groups in which some or all of the hydrogen atoms are substituted with a halogen atom such as a fluorine atom, chlorine atom or bromine atom, for example halogen-substituted C1-12 alkyl groups such as a 3-chloropropyl group and a 3,3,3-fluoropropyl group.

The straight-chain organohydrogenpolysiloxane of constituent (D) can have a hydrogen atom bound to a silicon atom only at the end(s) of the molecule, can have them only in a diorganosiloxane repeating unit of the molecule, or can have them both at the end of the molecule and in a diorganosiloxane repeating unit of the molecule. In one embodiment, the straight-chain organohydrogenpolysiloxane of constituent (D) has a hydrogen atom bound to a silicon atom only at both ends of the molecule.

The straight-chain organohydrogenpolysiloxane of constituent (D) can be represented, for example, by the general formula:

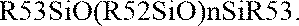

In the formula, each of the R5s, which can be the same or different, is a monovalent hydrocarbon group which does not have an aliphatic unsaturated carbon bond, or a hydrogen atom, where at least two R5s per molecule are hydrogen atoms. Specific examples of monovalent hydrocarbon groups which do not have an aliphatic hydrocarbon bond include C1-12 alkyl groups such as a methyl group, ethyl group, propyl group, isopropyl group, butyl group, isobutyl group, tert-butyl group, pentyl group, neopentyl group, n-hexyl group, cyclohexyl group, heptyl group, octyl group, nonyl group, decyl group, undecyl group and dodecyl group; C6-12 aryl groups such as a phenyl group, tolyl group, xylyl group and naphthyl group; C7-12 aralkyl groups such as a benzyl group, phenethyl group and phenylpropyl group; and these groups in which some or all of the hydrogen atoms are substituted with a halogen atom such as a fluorine atom, chlorine atom or bromine atom, for example halogen-substituted C1-12 alkyl groups such as a 3-chloropropyl group and a 3,3,3-fluoropropyl group. In addition, in the formula n is an integer ≥ 1, and is preferably an integer 10-1000, and more preferably 30-800.

Examples of constituent (D) include dimethylpolysiloxane with both ends of the molecular chain capped with dimethylhydrogensiloxy groups, a dimethylsiloxane/methylphenylsiloxane copolymer with both ends of the molecular chain capped with dimethylhydrogensiloxy groups, a dimethylsiloxane/methylhydrogensiloxane copolymer with both ends of the molecular chain capped with dimethylhydrogensiloxy groups, a dimethylsiloxane/methylhydrogensiloxane copolymer with both ends of the molecular chain capped with trimethylsiloxy groups, and a dimethylsiloxane/methylhydrogensiloxane/methylphenylsiloxane copolymer with both ends of the molecular chain capped with trimethylsiloxy groups, and mixtures of two or more thereof. In one embodiment, constituent (D) can be dimethylpolysiloxane with both ends of the molecular chain capped with dimethylhydrogensiloxy groups. A single constituent (D) can be employed, or two or more can be used together.

In one embodiment of the present invention, the straight-chain organohydrogenpolysiloxane of constituent (D) has a viscosity at 25° C. in the range of 1-10,000 mPa.s, preferably in the range 2-5000 mPa.s, and more preferably in the range 3-1000 mPa.s.

In the present invention, the ratio of the “total mols of hydrogen atoms bound to a silicon atom in the total organopolysiloxane included in the composition” relative to the “total mols of alkenyl groups bound to a silicon atom in the total organopolysiloxane included in the composition” is in the range 1-3, and thus, [(total mols of hydrogen atoms bound to a silicon atom in the total organopolysiloxane included in the composition)/(total mols of alkenyl groups bound to a silicon atom in the total organopolysiloxane included in the composition) = 1-3]. This ratio is more preferably 1-2, and even more preferably 1-1.5. When this ratio is smaller than 1, the curing time of the composition at low temperature becomes long.

The hydrosilylation reaction catalyst (E) in the present invention is a constituent used as the catalyst in order to accelerate the addition reaction(s) between the alkenyl groups bound to a silicon atom in aforementioned constituent (A) and (when present) constituent (B), and the hydrogen atoms bound to silicon atoms in aforementioned constituent (C) and (when present) constituent (D). Constituent (E) is a platinum-group-metal catalyst, and can include one or more platinum group metals selected from a group comprising platinum, rhodium, ruthenium, palladium, osmium and iridium. In one embodiment, a platinum-based catalyst, rhodium-based catalyst, and palladium-based catalyst can be given as examples of platinum-group-metal catalysts. The platinum group metal catalyst is preferably a platinum-based catalyst. Examples of platinum-based catalysts include finely powdered platinum, chloroplatinic acid, alcoholic solutions of chloroplatinic acid, platinum-alkenylsiloxane complexes, platinum-olefin complexes and platinum-carbonyl complexes. Examples of alkenylsiloxanes in platinum-alkenylsiloxane complexes include 1,3-divinyl-1,1,3,3-tetramethyldisiloxane, 1,3,5,7-tetramethyl-1,3,5,7-tetravinylcyclotetrasiloxane, alkenyl siloxanes in which some of the methyl groups in these alkenylsiloxanes are replaced by an ethyl group and/or phenyl group, etc., and alkenyl siloxanes in which some of the vinyl groups in these alkenylsiloxanes are replaced by an allyl group and/or hexenyl group, etc.

The quantity of constituent (E) in the composition is a quantity which is a catalytic quantity, of <15 ppm as the quantity of metal atoms included in the catalyst based on the total mass of organopolysiloxane having alkenyl groups bound to a silicon atom and organopolysiloxane having hydrogen atoms bound to a silicon atom in the composition. The quantity of catalyst in this specification is a quantity which enables the catalyst to catalyse the hydrosilylation reaction. In one embodiment of the present invention, the quantity of catalyst metal atoms included in constituent (E) in the composition, as the quantity of metal atoms included in the catalyst based on the total mass of organopolysiloxane having alkenyl groups bound to a silicon atom and organopolysiloxane having hydrogen atoms bound to a silicon atom in the composition, is preferably in the range 0.1-15 ppm, and more preferably in the range 0.5-10 ppm. Provided that the quantity of constituent (E) is within the range above, colouration of the hardened material formed from the curable silicone composition can be suppressed.

Other than constituents (A), (C) and (E) and discretionary constituents (B) and (D) above, a composition of the present invention can also include further discretionary ingredients within ranges which do not detract from the object of the present invention.

In one embodiment of the present invention, the curable silicone composition can include (F) a hydrosilylation reaction control agent in order to enable suitable control of the speed of hardening of the curable silicone composition. Examples of hydrosilylation control agents as constituent (F) include silylated acetylene compounds such as methyltris(3-methyl-1-butyn-3-oxy)silane, methylvinylbis(3-methyl-1-butyn-3-oxy)silane and trimethyl(cyclohexyl-1-ethyn-1-oxy)silane, alkyne alcohols such as 1-ethynylcyclohexanol, 2-methyl-3-butyn-2-ol, 3,5-dimethyl-1-hexyn-3-ol and 2-phenyl-3-butyn-2-ol, enyne compounds such as 3-methyl-3-penten-1-yne and 3,5-dimethyl-3-hexen-1-yne, alkenylcyclosiloxane compounds such as 1,3,5,7-tetramethyl-1,3,5,7-tetravinylcyclotetrasiloxane and 1,3,5,7-tetramethyl-1,3,5,7-tetrahexenylcyclotetrasiloxane, and benzotriazole. Although there is no restriction in the present invention as to the content of constituent (F), it is preferably in the range 0.001-3 parts by weight in a total of 100 parts by mass of organopolysiloxane having alkenyl groups bound to a silicon atom and organopolysiloxane having hydrogen atoms bound to a silicon atom in the composition.

In addition, in one embodiment of the present invention the curable silicone composition can also contain an adhesion conferring agent (G), in order to raise the adhesion of the hardened material to the substrate with which it is in contact during curing. As constituent (G), an organosilicon compound having per molecule at least one monovalent organic group containing an alkoxy group or epoxy group bound to a silicon atom is preferred. Examples of an alkoxy group here include a methoxy group, ethoxy group, propoxy group, butoxy group and methoxyethoxy group; a methoxy group is particularly preferred. Similarly, examples of epoxy-group-containing monovalent organic groups include glycidoxyalkyl groups such as a 3-glycidoxypropyl group and 4-glycidoxybutyl group, epoxycycloalkylalkyl groups such as a 2-(3,4-epoxycyclohexyl)ethyl group and 3-(3,4-epoxycyclohexyl)propyl group, and oxiranylalkyl groups such as a 4-oxiranylbutyl group and 8-oxiranyloctyl group; a glycidoxyalkyl group is especially preferred. Examples of groups other than monovalent organic groups containing an alkoxy group or epoxy group bound to a silicon atom include substituted or unsubstituted monovalent hydrocarbon groups such as alkyl groups, alkenyl groups, aryl groups, aralkyl groups and haloalkyl groups, acrylic-group-containing monovalent hydrocarbon groups such as a 3-methacryloxypropyl group, and a hydrogen atom. This organosilicon compound preferably has (a) silicon-atom-bound alkenyl group or silicon-atom-bound hydrogen atom. In addition, this organosilicon compound preferably has at least one epoxy-group-containing monovalent hydrocarbon group per molecule, because this can confer good adhesion for different types of substrate. Organosilane compounds, organosiloxane oligomers and alkyl silicates are examples of such organosilicon compounds. The molecular structure of the organosiloxane oligomers or alkyl silicates here can take the form of a straight-chain, straight-chain with one branch, branched-chain, cyclic or a network, for example; but a straight-chain, branched-chain or network form is particularly preferred. Specific examples of such organosilicon compounds include silane compounds such as 3-glycidoxypropyltrimethoxysilane, 2-(3,4-epoxycyclohexyl)ethyltrimethoxysilane, 3-methacryloxypropyltrimethoxysilane, siloxane compounds which have at least one silicon-atom-bound alkenyl group or silicon-atom-bound hydrogen atom and one silicon-atom-bound alkoxy group per molecule, mixtures of a silane compound or siloxane compound which has at least one silicon-atom-bound alkoxy group per molecule, and a siloxane compound which has at least one silicon-atom-bound hydroxyl group and silicon-atom-bound alkenyl group per molecule, methyl polysilicate, ethyl polysilicate, epoxy-group-containing ethyl polysilicate, and organopolysiloxane containing an epoxy group and an alkenyl group which is represented by average compositional formula:

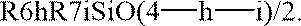

In these organopolysiloxanes which contain an epoxy group and an alkenyl group, R6 in the formula is an epoxy-group-containing monovalent organic group, exemplified by the same groups mentioned above; it is preferably a glycidoxyalkyl group. And R7 is a C1-12 alkyl group, C2-12 alkenyl group, C6-12 aryl group, or C7-12 aralkyl group, exemplified by the same groups mentioned above. Where ≥1 mol% of all R7s is/are (an) alkenyl group(s), and preferably ≥3 mol%, or >10 mol% is (an) alkenyl group(s). At least 3 mol%, or at least 10 mol% of all R7s is/are preferably (a) phenyl group(s). h is a number within the range 0.05-1.8, and preferably a number within the range 0.05-0.7, or a number within the range 0.1-0.6. Furthermore, i is a number in the range 0.10-1.80, and preferably a number in the range 0.20-1.80. Such organopolysiloxanes which contain an epoxy group and an alkenyl group can be prepared by cohydrolysis of an epoxy-group-containing alkoxysilane and an alkenyl-group-containing organosilane. It should be noted that the epoxy-group-containing organopolysiloxane can also contain a small quantity of alkoxy groups derived from the starting material thereof.

There is no particular restriction in the present invention as to the content of constituent (G). When constituent (G) is an organopolysiloxane having silicon-atom-bound alkenyl groups or silicon-atom-bound hydrogen atoms, the content of constituent (G) based on the total mass of organopolysiloxane having alkenyl groups bound to a silicon atom and organopolysiloxane having hydrogen atoms bound to a silicon atom in the composition is preferably in the range 0.01-10 mol%. When constituent (G) is not an organopolysiloxane having silicon-atom-bound alkenyl groups or silicon-atom-bound hydrogen atoms, the content of constituent (G) per a total of 100 parts by mass of organopolysiloxane having alkenyl groups bound to a silicon atom and organopolysiloxane having hydrogen atoms bound to a silicon atom is preferably in the range 0.01-10 mol%.

These compositions can also include further discretionary ingredients other than the constituents discussed above, provided that they do not detract from the object of the present invention. Examples of other discretionary ingredients which can be included in these compositions include inorganic fillers, organic fillers, phosphors, heat resistance agents, dyes, pigments, fire-proofing agents, additives for adjusting surface tension for levelling during screen printing (polydimethylsiloxane (PDMS) oil, modified oil or silane coupling agents, etc.), antioxidants (cerium, etc.), weather resistance agents, and solvents.

Inorganic fillers include fillers for reinforcing constituent (B) for conferring mechanical strength on the hardened material and raising protection or adhesion, etc., for example fumed silica, precipitated silica, fused silica, baked silica, fumed titanium dioxide, quartz, calcium carbonate, silicon diatomite, aluminium oxide aluminium hydroxide, zinc oxide, zinc carbonate and glass beads, because they confer mechanical strength on the hardened material and increase protection or adhesion. These reinforcing fillers can also be surface-treated with an organoalkoxysilane such as methyltrimethoxysilane, an organohalosilane such as trimethylchlorosilane, an organosilazane such as hexamethyldisilazane, or an siloxane oligomer selected from α,ω-silanol group-capped dimethylsiloxane oligomers, α,ω-silanol group-capped methylphenylsiloxane oligomers, and α,ω-silanol group-capped methylvinylsiloxane oligomers etc. Further reinforcing fillers include fibre fillers such as calcium metasilicate, potassium titanate, magnesium sulfate, zeolite, Zonolite, aluminium borate, rock wool and glass fibre.

Inorganic fillers can also be heat-conducting fillers or electrically-conducting fillers; heat-conducting fillers or electrically-conducting fillers include finely powdered metals such as gold, silver, nickel, copper or aluminium, fine powders of finely powdered ceramic, glass, quartz or organic resin, etc., with a metal such as gold, silver, nickel or copper vapour deposited or plated onto the surface thereof, metal compounds such as aluminium oxide, magnesium oxide, aluminium nitride, boron nitride and zinc oxide, graphite, and mixtures of two or more thereof.

Pigments include, for example, white pigments and black pigments; white pigments include metal compounds such as titanium dioxide, aluminium oxide, zinc oxide, zirconium oxide and magnesium oxide, hollow fillers such as glass balloons and glass beads, and also barium sulfate, zinc sulfate, barium titanate, aluminium nitride, boron nitride and antimony oxide. Carbon black may be cited as a black pigment.

Phosphors include substances widely employed in light-emitting diodes (LEDs), for example phosphors emitting yellow, red, green or blue light; examples include oxide-based phosphors, oxynitride-based phosphors, nitride-based phosphors, sulfate-based phosphors, and oxysulfide-based phosphors. Examples of oxide-type phosphors include cerium ion-doped yttrium-aluminium-garnet type YAG green-yellow light-emitting phosphors, cerium ion-doped terbium-aluminium-garnet type TAG yellow light-emitting phosphors, and cerium and europium ion-doped silicate green-yellow-light-emitting phosphors. Examples of oxynitride-type phosphors include europium ion-doped silicon-aluminium-oxygen-nitrogen type SiAlON red-green light-emitting phosphors. Examples of nitride-type phosphors include europium ion-doped calcium-strontium-aluminium-silicon-nitrogen type CASN red light-emitting phosphors. Examples of sulfide-type phosphors include copper ion or aluminium ion-doped ZnS green light-emitting phosphors. Examples of oxysulfide-type phosphors include europium ion-doped Y2O2S red light-emitting phosphors. A single one of these phosphors can be employed, or a combination of various types can be employed.

Organic fillers include fine particulate silicones, for example, fine particulate non-reactive silicone resins and fine particulate silicone elastomers. Fine particulate silicone elastomers can take various forms, such as round, flattened and irregularly shaped, but from the point of view of dispersibility they are preferably round, and within this they are more preferably spherical.

Provided that there is no adverse effect on the object of the invention, there is no restriction as to the quantities of discretionary ingredients. For example, in one embodiment of the present invention, the composition can include (a) phosphor(s) in a quantity of 10-80 mass% based on the total mass of this composition. In one embodiment of the present invention, the composition can also include an inorganic filler, for example titanium oxide, in a quantity of 10-80 mass% based on the total mass of this composition. In one embodiment of the present invention, the composition can include a pigment, for example carbon black, in a quantity of 0.01-50 mass% based on the total mass of this composition. In one embodiment of the present invention, the composition can include silica, for example fumed silica, in a quantity of 0.01-80 mass% based on the total mass of this composition.

In one embodiment of the present invention, the quantity of organopolysiloxane having alkenyl groups bound to a silicon atom and organopolysiloxane having hydrogen atoms bound to a silicon atom in the composition, based on the total mass of the composition should be ≥20 mass%, ≥40 mass%, ≥60 mass%, ≥80 mass%, or ≥90 mass%, and should be ≤97 mass% or ≤99 mass%.

Although this composition will promote curing at room temperature or by heating, heating is preferred in order to speed up curing. This heating temperature is preferably in the range 50-200° C., and more preferably 50-90° C.

A curable silicone composition of the present invention can be used as photosemiconductor sealing material. Thus, one embodiment of the present invention offers photosemiconductor sealing material of a curable silicone composition of the present invention.

Hardened material of the present invention will next be described in detail.

Hardened material of a curable silicone composition of the present invention is characterized in that it is constituted by curing a curable silicone composition described above. There is no particular restriction as to the form of the hardened material; for example, it can be in the form of a sheet or film, etc. Hardened material can be handled as a single item as such, but it can be handled in a state covering or sealing a photosemiconductor element, etc.

A photosemiconductor device of the present invention will next be described in detail.

A photosemiconductor device of the present invention is characterized in that the photosemiconductor element(s) is/are sealed with hardened material of a curable silicone composition described above. Examples of such photosemiconductor devices of the present invention include light-emitting diodes (LEDs), photocouplers and charge-coupled devices (CCDs). Examples of photosemiconductor devices also include light-emitting diode (LED) chips and solid-state imaging elements.

A cross-sectional drawing of a surface-mounted LED which is an example of a photosemiconductor device of the present invention is presented in FIG. 1. In the LED shown in FIG. 1, the light-emitting element (LED chip) 1 is die-bonded onto a lead frame 2, and this light-emitting element (LED chip) 1 and lead-frame 3 are wire-bonded with bonding wire 4. A frame member 5 is set around this light-emitting element (LED chip) 1, and the light-emitting element (LED chip) 1 is sealed inside this frame 5 with hardened material of a curable silicone composition 6.

In one example of a process for producing the surface-mounted LED shown in FIG. 1, the light-emitting element (LED chip) 1 is die-bonded onto a lead frame 2, and this light-emitting element (LED chip) 1 and lead-frame 3 are wire-bonded with metal bonding wire 4; then a curable silicone composition of the present invention is filled inside the frame member 5 set around this light-emitting element (LED chip) 1, followed by curing by heating at 50-200° C. and preferably 50-90° C.

### EXAMPLES

The present invention is described in more detail below by means of examples; however, the present invention is not restricted to the description in the examples.

Example, reference example and comparative example curable silicone compositions with the compositions shown in Table 1 were prepared by using the constituents below. In the formulae below Me represents a methyl group, Vi represents a vinyl group, Ph represents a phenyl group, and Ep represents a 3-glycidoxypropyl group.

The following constituents were employed as constituent (A).

### Constituent (A-1)

Dimethylpolysiloxane with both ends of the molecular chain capped with dimethylvinylsiloxy groups having the formula:

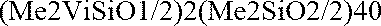

(vinyl group content = 1.5 wt%; viscosity =60 mPa.s);

### Constituent (A-2)

Dimethylpolysiloxane with both ends of the molecular chain capped with dimethylvinylsiloxy groups having the formula:

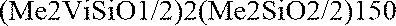

(vinyl group content = 0. 4 wt%;viscosity = 380 mPa.s);

### Constituent (A-3)

Dimethylpolysiloxane with both ends of the molecular chain capped with dimethylvinylsiloxy groups having the formula:

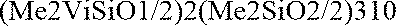

(vinyl group content = 0. 2 wt%; viscosity =2000 mPa.s);

### Constituent (A-4)

Dimethylpolysiloxane with both ends of the molecular chain capped with dimethylvinylsiloxy groups having the formula:

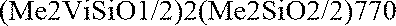

(vinyl group content = 0.1 wt%; viscosity = 43,000 mPa.s).

The following constituents were employed as constituent (B).

### Constituent (B-1)

Vinyl-group-containing organopolysiloxane, resin having the average compositional formula:

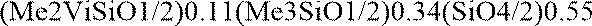

(vinyl group content = 4.2 wt%; solid at 25° C.);

### Constituent (B-2)

Vinyl-group-containing organopolysiloxane, resin having the average compositional formula:

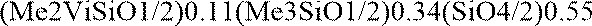

(vinyl group content = 2.4 wt%; solid at 25° C.).

The following constituents were employed as constituent (C).

### Constituent (C-1)

Vinyl-group-containing organopolysiloxane, resin having the average compositional formula:

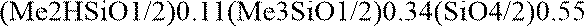

(silicon-atom-bonded hydrogen atom content = 0.9 wt%, viscosity =30 mPa.s, number average molecular weight (Mn)=1300, weight average molecular weight (Mw)=1700, molecular weight distribution (Mw/Mn)=1.3, with a network molecular structure);

### Constituent (C-2)

Vinyl-group-containing organopolysiloxane, resin having the average compositional formula:

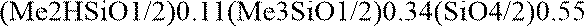

(silicon-atom-bonded hydrogen atom content = 0.65 wt%, number average molecular weight (Mn)=700, weight average molecular weight (Mw)=750, molecular weight distribution (Mw/Mn)=1.1, with a network molecular structure).

The following constituents were employed as constituent (D).

### Constituent (D-1)

Dimethylpolysiloxane with both ends of the molecular chain capped with dimethylvinylsiloxy groups having the formula:

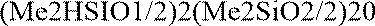

(silicon-atom-bonded hydrogen atom content = 0.1 wt%, viscosity = 20 mPa.s).

### Constituent (D-2)

Dimethylpolysiloxane with both ends of the molecular chain capped with dimethylvinylsiloxy groups having the formula:

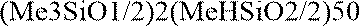

(silicon-atom-bonded hydrogen atom content = 1.6 wt%; viscosity =20 mPa.s).

### Constituent (D-3)

Methylhydrogenpolysiloxane with both ends of the molecular chain capped with trimethylsiloxy groups, having the formula:

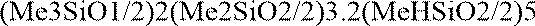

(silicon-atom-bonded hydrogen atom content = 0.8 wt%; viscosity =20 mPa.s).

The following constituent was employed as constituent (E).

### Constituent (E-1)

1,3-divinyl-1,1,3,3-tetramethyldisiloxane solution of platinum-1,3-divinyl-1,1,3,3-tetramethyldisiloxane complex (platinum content =3 mass%)

It should be noted that in Table 1, the content of constituent (E) is shown as mass of platinum metal relative to the total mass of organopolysiloxane having alkenyl groups bound to a silicon atom and organopolysiloxane having hydrogen atoms bound to a silicon atom (ppm: parts per million).

The following constituent was employed as constituent (F).

Constituent (F-1): ethynylcyclohexan-1-ol.

The following constituent was employed as constituent (G).

### Constituent (G-1)

Organopolysiloxane, having the average compositional formula:

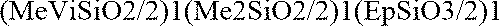

(vinyl group content = 5.5 wt%).

In the tables, H/Vi represents (total mols of hydrogen atoms bound to a silicon atom in the total organopolysiloxane included in the composition)/(total mols of vinyl groups bound to a silicon atom in the total organopolysiloxane included in the composition).

The curable silicone compositions of the different examples, reference examples and comparative examples were prepared by mixing all of the ingredients uniformly with the compositions (parts by mass) shown in Table 1 and Table 2. The properties of the curable silicone compositions thus prepared were specified by the methods indicated below. The results are presented in Table 1. It should be noted that an empty properties column in Table 1 indicates that the respective property was not measured for that composition.

### Curing Time at 90° C.

With 6 g of the curable silicone composition in a moving die rheometer (MDR), the time for torque to reach a plateau at 90° C. was taken to be the curing time when the entire composition had been cured. A curing time within 5 minutes was taken to be conformity. In the tables “min” means “minutes”.

### Viscosity

The viscosities of each of the constituents and of each of the compositions were measured by employing a rotational viscometer in accordance with JIS K7117-1: specifically, they were measured at 25° C. using an Anton Paar MCR 302, with a 40 mm2 cone plate, at a constant shear-speed of 20/s.

### Transmissivity of the Hardened Material

Hardened material 2-mm thick was produced from 3 g of the curable composition heated for 5 minutes at 90° C. using a metal mod (10 mm×50 mm×2 mm). The transmissivity of the hardened material (wavelength 450 nm) was measured. Transmissivity of ≥90% was taken to be conformity.

### Curing Shrinkage

Hardened material was produced from 30 g of the curable composition by pressing for 5 minutes at 90° C. using a metal mould (10 cm×15 cm×1 mm); this hardened material was cooled to ambient temperature and then the dimensions were measured and the percentage change in dimensions was taken to be the curing shrinkage. Within 1% was taken to be conformity. This curing shrinkage is equivalent to volume shrinkage in the composition during curing.

TABLE 1

| | | | Example 1 | Example 2 | Example 3 | Example 4 | Example 5 | Example 6 |
|---|---|---|---|---|---|---|---|---|
| Composition constituent | (A) Constituent | (A-1) | 46.0 | | | | 46.0 | 46.0 |
| | | (A-2) | 48.7 | 97.8 | | | 28.7 | 49.7 |
| | | (A-3) | | | 98.3 | 97.5 | | |
| | | (A-4) | | | | | 20.0 | |
| | (B) Constituent | (B-1) | | | | | | |
| | | (B-2) | | | | | | |
| | (C) Constituent | (C-1) | 4.7 | 1.7 | 1.7 | | 4.7 | 3.7 |
| | | (C-2) | | | | 2.5 | | |
| | (D) Constituent | (D-1) | | | | | | |
| | | (D-2) | | | | | | |
| | | (D-3) | | | | | | |
| | (E) Constituent | (E-1) | 8 ppm | 8 ppm | 1.5 ppm | 0.5 ppm | 8 ppm | 8 ppm |
| | (F) Constituent | (F-1) | 0.02 | 0.02 | 0.02 | 0.02 | 0.02 | 0.02 |
| | (G) Constituent | (G-1) | 0.5 | 0.5 | | | 0.5 | 0.5 |
| Property | H/V i | | 1.3 | 1 | 2 | 2 | 1.3 | 1 |
| | Curing time at 90° C. | | 1-min | 2 min | 1 min | 3 min | 2 min | 5 min |
| | Viscosity (mP a-s) | | 200 | 300 | 700 | 700 | 800 | 200 |
| | Transmissivity | | Conformity | Conformity | Conformity | Conformity | Conformity | Conformity |
| | Curing shrinkage | | 0.50% | 0.50% | 0.50% | 0.50% | 0.50% | 0.50% |

TABLE 2

| | | | Reference Example 7 | Reference Example 8 | Reference Example 9 | Reference Example 10: | Reference Example 11 |
|---|---|---|---|---|---|---|---|
| Composition constituent | (A) Constituent | (A-1) | | | | | |
| | | (A-2) | | | | | 51.6 |
| | | (A-3) | 86.4 | 84.7 | 80.8 | 77.6 | 19.5 |
| | | (A-4) | | | | | |
| | (B) Constituent | (B-1) | 10.1 | 10.1 | 12.7 | 15.2 | 20.0 |
| | | (B-2) | | | | | |
| | (C) Constituent | (C-1) | 3.5 | | | | |
| | | (C-2) | | 5.2 | 6.0 | 7.0 | 8.4 |
| | (D) Constituent | (D-1) | | | | | |
| | | (D-2) | | | | | |
| | | (D-3) | | | 3 | | |
| | (E) Constituent | (E-1) | 1.5 ppm | 1.5 ppm | 8 ppm | 8 ppm | 8 ppm |
| | (F) Constituent | (F-1) | 0.02 | 0.02 | 0.02 | 0.02 | 0.02 |
| | (G) Constituent | (G-1) | | | 0.5 | 0.5 | 0.5 |
| Property | H/V i | | 1.5 | 1.5 | 1.5 | 1.5 | 1.5 |
| | Curing time at 90° C. | | 4 min | 2 min | 3 min | 4 min | 5 min |
| | Viscosity (mPa·s) | | 500 | 500 | 700 | 800 | 1000 |
| | Transmissivity | | Conformity | Conformity | Conformity | Conformity | Conformity |
| | Curing shrinkage | | 0.50% | 0.50% | 0.50% | 0.50% | 0.50% |

TABLE 3

| | | | | | | | | | | |
|---|---|---|---|---|---|---|---|---|---|---|
| | | | Comparative Example 12 | Comparative Example 13 | Comparative Example 14 | Comparative Example 15 | Comparative Example 16 | Comparative Example 17 | Comparative Example 18 | Comparative Example 19 |
| Composition constituent | (A) Constituent | (A-1) | | | | | | 46.0 | 46.0 | 46.0 |
| | | (A-2) | | 76.6 | 64.0 | 39.4 | 39.5 | 47.5 | 50.5 | 51.2 |
| | | (A-3) | 86.9 | 10.4 | | | 24.7 | | | |
| | | (A-4) | | | | | | | | |
| | (B) Constituent | (B-1) | 10.1 | 10.6 | | | 25.3 | | | |
| | | (B-2) | | | 30.3 | 30.3 | | | | |
| | (C) Constituent | (C-1) | | | 5.5 | | | | 2.9 | 2.2 |
| | | (C-2) | | | | | 10.0 | | | |
| | (D) Constituent | (D-1) | | | | 30.1 | | | | |
| | | (D-2) | 3.5 | 1.9 | | | | | | |
| | | (D-3) | | | | | | 5.9 | | |
| | (E) Constituent | (E-1) | 1.5 ppm | 8 ppm | 8 ppm | 8 ppm | 8 ppm | 8 ppm | 8 ppm | 8 ppm |
| | (F) Constituent | (F-1) | 0.02 | 0.02 | 0.02 | 0.02 | 0.02 | 0.02 | 0.02 | 0.02 |
| | (G) Constituent | (G-1) | | 0.5 | 0.5 | 0.5 | 0.5 | 0.5 | 0.1 | 0.5 |
| Property | H/V i | | 2.4 | 1 | 1.3 | 1 | 1.5 | 1.3 | 0.8 | 0.6 |
| | Curing time at 90° C. | | >10 min | >10 min | >10 min | >10 min | >5 min | >10 min | 8 min | >10 min |
| | Viscosity (mpa·s) | | | | | | | | | |
| | Transmissivity | | | | | | | | | |
| | Curing shrinkage | | | | | | | | | |

As shown in the examples, the curable silicone compositions of the present invention can cure rapidly, within 5 minutes. Moreover, in the examples the viscosity of the composition, the transparency of the hardened material, and curing shrinkage during curing of the compositions were also at the desired levels. From the results of the examples, reference examples and Comparative Examples 14-16 it was clear that rapid curing within 5 minutes was possible with a content of constituent (B) (i.e. organopolysiloxane resin which has at least two alkenyl groups bound to a silicon atom per molecule) in the curable silicone composition of 0-20 mass%, but curing within 5 minutes could not be achieved when the content of constituent (B) was 25-30 mass%. As shown in Comparative Example 12 and 13, even when the content of constituent (B) was ca. 10 mass%, curing within 5 minutes could not be achieved when constituent (C) was not included.

As regards the relationship between the value of (total mols of hydrogen atoms bound to a silicon atom in the total organopolysiloxane included in the composition)/(total mols of alkenyl groups bound to a silicon atom in the total organopolysiloxane included in the composition) in the curable silicone composition and curing speed, it is clear from the results of the examples and Comparative Examples 18 and 19 that when this ratio is ≤0.8, it is impossible to achieve rapid curing within 5 minutes.

### INDUSTRIAL APPLICABILITY

Curable compositions of the present invention can be used as sealing materials or covering materials for photosemiconductors such as light-emitting diodes.

### Key

1 Light-emitting element
2 Lead frame
3 Lead frame
4 Bonding wire
5 Frame member
6 Hardened material of a curable silicone composition

1. A curable silicone composition comprising
(A) straight-chain organopolysiloxane which has at least two alkenyl groups bound to a silicon atom per molecule, and a quantity of aryl groups bound to a silicon atom of≥0 mol% and <5 mol% based on the total mols of organic groups bound to a silicon atom: 89-99 mass% based on the total mass of organopolysiloxane having alkenyl groups bound to a silicon atom and organopolysiloxane having hydrogen atoms bound to a silicon atom in the aforementioned composition,
(B) organopolysiloxane resin which has at least two alkenyl groups bound to a silicon atom per molecule: 0-10 mass% based on the total mass of organopolysiloxane having alkenyl groups bound to a silicon atom and organopolysiloxane having hydrogen atoms bound to a silicon atom in the aforementioned composition,
(C) organohydrogenpolysiloxane resin which has a network molecular structure with at least two hydrogen atoms bound to a silicon atom per molecule, selected from the group consisting of (C1) organohydrogenpolysiloxane resins which have a network molecular structure which has at least two hydrogen atoms bound to a silicon atom per molecule, and includes a siloxane unit represented by SiO4/2 (Q unit), and
(C2) organohydrogenpolysiloxane resins which have a network molecular structure with at least two hydrogen atoms bound to a silicon atom per molecule, include a siloxane unit represented by R3SiO3/2 (T unit) and a siloxane unit represented by R33SiO½ (M unit), and do not include a siloxane unit represented by R32SiO2/2 (D unit) or a siloxane unit represented by SiO4/2 (Q unit), (in the formulae, each of the R3s, which can be the same or different is a monovalent hydrocarbon group which does not have an aliphatic unsaturated carbon bond, or a hydrogen atom): 1-11 mass% based on the total mass of organopolysiloxane having alkenyl groups bound to a silicon atom and organopolysiloxane having hydrogen atoms bound to a silicon atom in the aforementioned composition, and
(E) a hydrosilylation reaction catalyst: a quantity, which is a catalytic quantity, of <15 ppm as the quantity of metal atoms included in the catalyst based on the total mass of organopolysiloxane having alkenyl groups bound to a silicon atom and organopolysiloxane having hydrogen atoms bound to a silicon atom in the aforementioned composition, wherein
(total mols of hydrogen atoms bound to a silicon atom in the total organopolysiloxane included in the composition) / (total mols of alkenyl groups bound to a silicon atom in the total organopolysiloxane included in the composition) = 1-3.

2. A hardened material of a curable silicone composition according to claim 1.

3. A photosemiconductor sealing material composition comprising a curable silicone according to claim 1.

4. A photosemiconductor device in which the photosemiconductor element is sealed with hardened material of a curable silicone composition according to claim 1.

5. A process for producing photosemiconductor devices, which includes sealing of photosemiconductor elements with hardened material of a curable silicone composition according to claim 1.
